(19) United States
(12) Patent Application Publication
(10) Pub. No.: US 2026/0191045 A1
(43) Pub. Date: Jul. 2, 2026

(54) INTERCONNECTS EMBEDDED IN MOLD PLUG IN CORE FOR PACKAGE LAYER COUNT REDUCTION

(71) Applicant: Intel Corporation, Santa Clara, CA (US)

(72) Inventors: Eng Huat Goh, Paya Terubong (MY); Seok Ling Lim, Bukit Mertajam (MY); Jiun Hann Sir, Gelugor (MY); Yean Ling Soon, Butterworth (MY); Telesphor Kamgaing, Chandler, AZ (US)

(73) Assignee: Intel Corporation, Santa Clara, CA (US)

(21) Appl. No.: 19/003,362

(22) Filed: Dec. 27, 2024

(51) Int. Cl. H01L 23/498; H01L 23/538

(52) U.S. Cl. CPC H10W 70/635; H10W 70/611; H10W 70/65; H10W 70/66; H10W 90/701

(57) ABSTRACT

Multi-chip device structures include a package substrate. A substrate core includes a plurality of first conductive vias, a through hole, and a plug in the through hole comprising a dielectric material and a plurality of second conductive vias. The substrate core is between a front-side routing structure and a backside routing structure. A first IC device is coupled with first contacts at a surface of the front-side routing structure. A second IC device is coupled with second contacts at the surface. The front-side routing structure couples first ones of the first contacts with first ones of the second contacts. The backside routing structure couples the first conductive vias with the second conductive vias, and couples second ones of the first contacts with second ones of the second contacts. A pitch of the first contacts is greater than a pitch of the second contacts.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC die from physical damage and support electrical contacts suitable for further connecting to other IC chips and a host component, such as a printed circuit board (PCB) or interposer. Multiple IC chips can be co-assembled, for example, into a multi-die package (MCP) in which the IC die are attached to a package substrate. In the IC industry, the process of fabricating a package is often referred to as packaging or assembly.

A package substrate may include a core and build-up layers over top and bottom sides of the core. The build-up layers may be symmetrical, i.e., the same number of build-up layers are provided on each side of the core. It is desirable to keep the number of build-up layers to a minimum. With fewer layers or levels, IC device package substrates may be thinner, cost less per unit, and/or the total number of substrates that can be produced with a given manufacturing capacity can be increased in comparison to package substrates with more layers.

The build-up layers of a package substrate may include metallization layers between layers of dielectric. The metallization layers may include routing layers for routing electrical signals that include lines (i.e., traces). In IC device packages in which signals are transmitted at high frequencies, electromagnetic interference (EMI) and cross talk are concerns. As such, the build-up layers of a package substrate may also include layers to shield the signal lines from EMI and cross talk.

Next generation MCPs may require greater interconnect density than needed in past designs. A top surface of a package substrate includes a pattern of interconnects (bumps or contacts) that corresponds to a bump pattern on the bottom of an IC die. The pitch or distance between interconnects in next generation MCPs may be smaller than the pitch of earlier generations of MCPs.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIG. 1 illustrates a flow diagram of methods for forming a device package structure comprising a package substrate with a core comprising a conductive vias embedded in a plug within a hole in the core, in accordance with some embodiments;

FIGS. 2A through 2D illustrate cross-sectional views of a workpiece evolving to a plug comprising conductive vias as selected operations in the methods illustrated in FIG. 1 are performed, in accordance with some embodiments;

FIG. 2E illustrates a plan view of a plug comprising conductive vias, in accordance with some embodiments;

FIG. 3 is a schematic illustration of power and data signals associated with a memory device, in accordance with some embodiments;

FIGS. 4A through 4E illustrate cross-sectional views of a workpiece evolving to include a device package structure comprising multiple IC devices attached to a package substrate with a core comprising a conductive vias embedded in a plug within a hole in the core as selected operations in the methods illustrated in FIG. 1 are performed, in accordance with some embodiments;

FIG. 5 illustrates a system including one of the multi-chip device packages illustrated in FIG. 4E attached to a host component with FLI features, in accordance with some embodiments;

FIG. 6 illustrates a mobile computing platform and a data server machine employing a multi-chip device package, in accordance with some embodiments; and

FIG. 7 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

In an example, an IC device package includes one 128-megabit (MB) double data rate (DDR) memory chip, the package substrate requires five (5) build-up layers on a first side of a core. The build-layers include two metallization levels (e.g., 2F and 4F) that include lines to carry DDR data signals. Each may metallization level may include a pair of lines that are close together in order to implement differential signaling. The metallization levels are interleaved with three levels (e.g., 1F, 3F, and 5F) of ground (Vss) planes. The ground (Vss) planes provide electrical shielding above and below the signal lines. Because the same number of build-up layers may be required on each side of the core, the package substrate generally requires a total of ten (10) build-up layers.

Next generation MCPs may require more memory. In a second example, an IC device package includes a package substrate and two 128 MB DDR memory chips. The package substrate requires nine (9) build-up layers on a first side of a core. The build-layers include four metallization levels (e.g., 2F, 4F, 6f, and 8f) that include signal lines to carry DDR data signals. The metallization levels are interleaved with five levels of ground (Vss) planes (e.g., 1F, 3F, 5F, 7f, and 9f). For a symmetrical build-up over the core, the package substrate requires a total of eighteen (18) build-up layers (nine layers over each surface). An alternative architecture that can accommodate two 128 MB DDR memory chips, but requires fewer than eighteen build-up layers is desirable.

A multi-die package (MCP) the includes one or more DDR memory chips may include other IC devices that have a finer bump pitch patten than the memory chips. An MCP architecture that can accommodate chips with different sized bump pitch patterns is desirable.

Integrated circuit (IC) device package structures that include a package substrate comprising a core between first and second routing structures are described herein. The core comprises a plurality of first conductive vias and a plug in a hole through the core. The plug comprises a dielectric material and second conductive vias extending through the dielectric material. The package substrate includes first and second contacts on a surface, wherein a feature pitch of the first contacts is greater than a feature pitch of the second contacts. The package substrate advantageously couples the first contacts with second contacts in an architecture that comprises a ten (10) build-up layers.

One advantage of embodiments described herein is that interconnects may be provided with a higher density than in known designs. For example, data signals from a DDR memory received on bumps having a 110 μm bump pitch may not be transmitted vertically down to 1b-5b build-up layers using through-core vias due to laser through hole (LTH) pitch constraints, e.g., LTHs are greater than 230 μm. Embodiments described herein provide a through-core vertical transmission path formed of small pitch of copper columns having a pitch less than or equal to 110 μm, which allows connections between top to bottom build-up layers. Other advantages of embodiments described herein is that package layer count may be lower than in other designs, which reduces both manufacturing cost and time. Package layer count may be reduced from 18 to 10 layers. Another advantage is that the lower package layer count also reduces the z-height of a multi-chip device package. Reducing the layer count from 18 to 10 may correspond with a z-height reduction of about 650 μm. A further advantage of embodiments described herein is that differential pairs of DDR memory signals are shielded from EMI and cross talk.

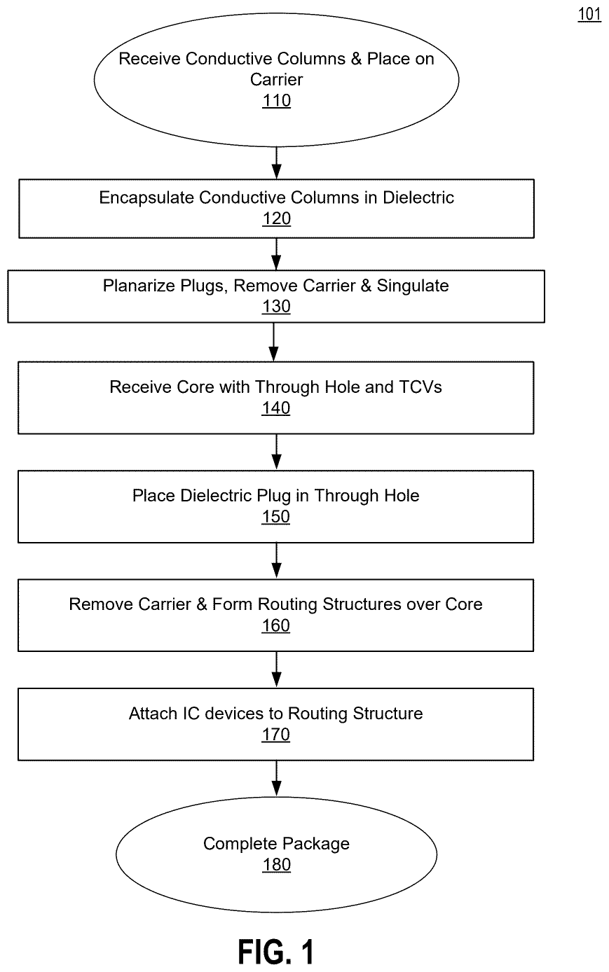

Multi-chip device structures comprising a package substrate with a core comprising a conductive vias embedded in a plug in the core may be fabricated according to approaches in which the plug is first formed followed by fabrication of the package substrate and addition of IC chips. After plug formation, the plug may be placed in a hole in the core, layers comprising metallization may be built up over the core, and IC devices may be attached to the package substrate. Different fabrication methods may be practiced to form multi-chip device structures having one or more of the features or attributes described herein. FIG. 1 illustrates a flow diagram of methods 101 for forming a package substrate with a core comprising a conductive vias embedded in a plug in the core, in accordance with some embodiments.

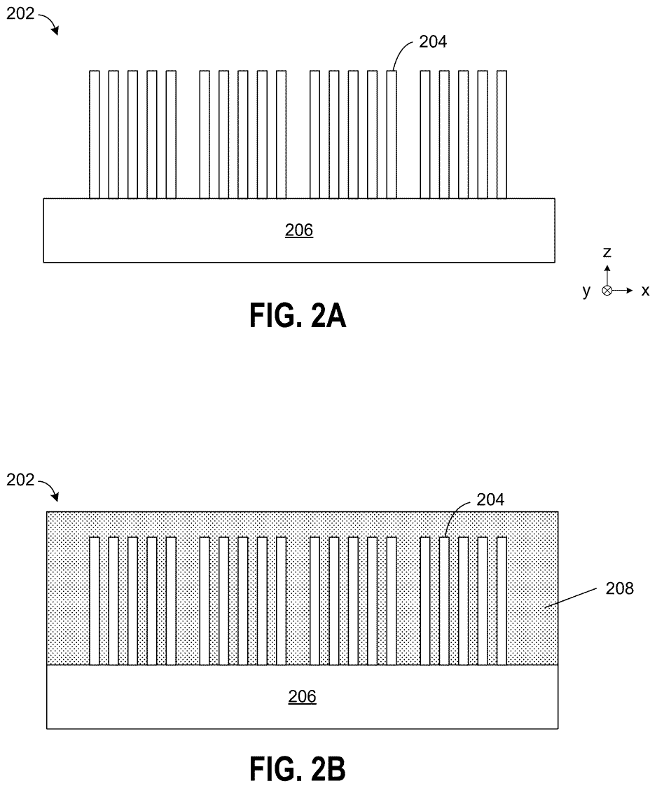

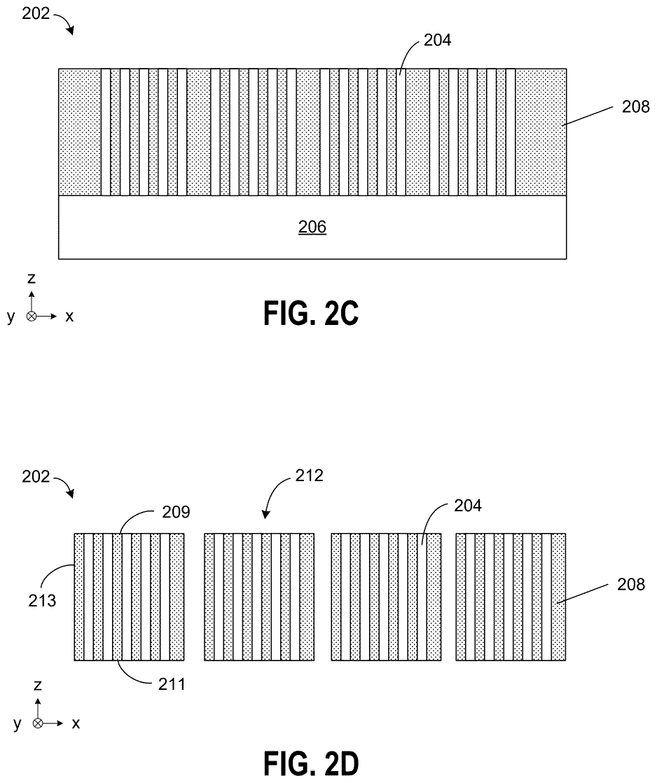

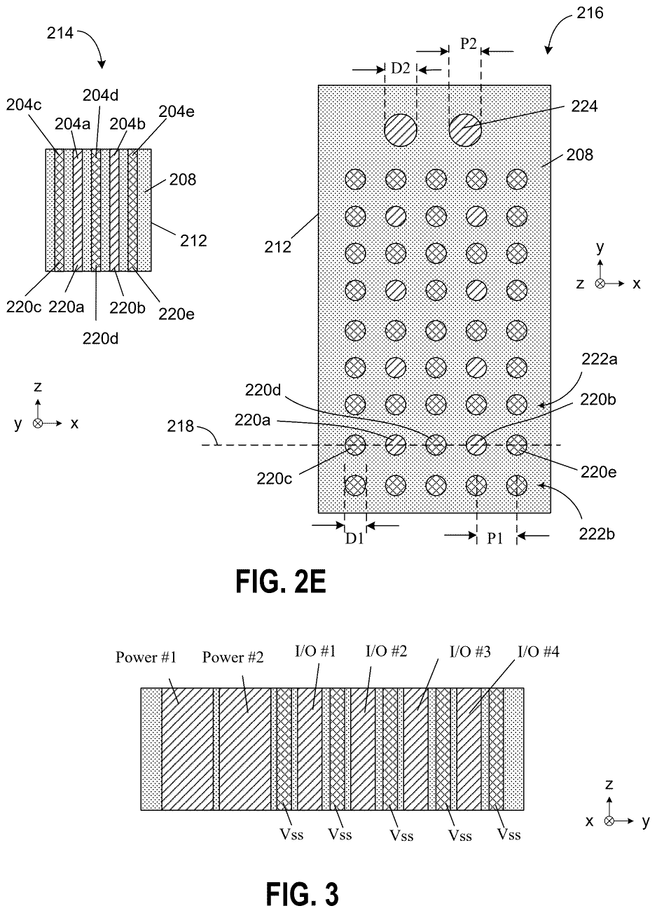

Methods 101 begin at input block 110 with the receipt of conductive columns that have been fabricated upstream of methods 101. The example in FIG. 2A illustrates a first workpiece 202 comprising conductive columns 204 after the columns have been attached to a carrier 206. In some examples, the carrier 206 is received with the conductive columns 204 attached. In other examples, the conductive columns may be placed on the carrier using in suitable method, e.g., with a pick and place tool. The conductive columns 204 may comprise any suitable metal or metals, such as Cu. The carrier 206 may be any carrier or handle substrate known in the industry to be suitable.

Returning to FIG. 1, methods 101 continue at block 120 where the conductive columns are encapsulated in a dielectric material, e.g., mold. The example in FIG. 2B illustrates first workpiece 202 after the conductive columns 204 have been encapsulated in a dielectric material 208. The dielectric material 208 may be a moldable dielectric material, such as an epoxy material. Dielectric material 208 may be any suitable an organic material or organic plastic material, such as an epoxy material. In some examples, dielectric material 208 may be a thermoplastic material, i.e., any plastic polymer material that becomes pliable or moldable at a certain elevated temperature and solidifies upon cooling. Dielectric material 208 may be any alternative material known to be suitable for IC chip packaging applications. Dielectric material 208 may also comprise any of a variety of fillers in some examples. Any suitable method may be employed to encapsulate conductive columns 204 in dielectric material 208.

In an alternative embodiment, a dielectric material may be placed on the carrier, holes formed in the dielectric, and the holes filled with conductive material in a semi-additive process. However, methods in which the dialectic material is formed over conductive columns attached to a carrier may be less expensive than other methods, e.g., a semi-additive process.

Referring to FIG. 1A, methods 101 continue at block 130 where the dielectric material and columns are been planarized or grinded to a desired height, the structure comprising the conductive columns encapsulated in a dielectric material is removed from the carrier, and singulated into individual plugs at block 120. FIG. 2C is a cross-sectional view of first workpiece 202 after the dielectric material and columns have been planarized or grinded to a desired height. FIG. 2D is a cross-sectional view of first workpiece 202 after the carrier has been removed the dielectric material comprising encapsulated conductive columns and singulated to create individual plugs 212, in accordance with some embodiments. In the example illustrated in FIG. 2D, each plug 212 includes five conductive columns 204 in the x-direction. In other examples, plugs 212 may include more or fewer conductive columns in the x-direction. Each plug 212 includes top surface 209, bottom surface 211, and sidewalls 213.

FIG. 2E includes cross-sectional view 214 and a plan view 216 of one of the plugs 212 that illustrate some dimensions for conductive columns 204, in accordance with some embodiments. Cross-sectional view 214 is taken along dashed line 218. Cross-sectional view 214 illustrates multiple instances of conductive columns 204, i.e., conductive columns 204a, 204b, 204c, 204d, and 204e.

Because the conductive columns 204 may be used to hold a voltage or conduct an electric signal in a multi-chip device structure, the conductive columns 204 are also referred to herein as vias or conductive vias 220. Cross-sectional view 214 and a plan view 216 also illustrate some signal assignments for conductive vias 220, in accordance with some embodiments.

In the illustrated example, conductive vias 220a and 220b may be used for a differential pair of data signals for an Input/Output (I/O) channel of a DDR memory. conductive vias 220c, 220d, and 220e may be coupled with a reference voltage, e.g., a ground voltage Vss, to shield the signal lines, i.e., conductive vias 220a, 220b, from EMI and cross talk. In addition, conductive vias in row 222a and row 222b may be coupled with the reference voltage to shield conductive vias 220a, 220b from EMI and cross talk. In the illustrated example, conductive vias 224 may be used for a power signal, e.g., a DDR power signal.

Conductive vias 220 (conductive columns 204) may have a first diameter D1. In some embodiments, the first diameter D1 is less than 100 microns. In addition, conductive vias 220 may have a first feature pitch P1. In some embodiments, the first feature pitch P1 is 110 microns or less.

Conductive vias 224 (conductive columns 204) may have a second diameter D2. Second diameter D2 may be any diameter suitable for power delivery. In some embodiments, the second diameter D2 is between 75 and 250 microns. In addition, conductive vias 224 may have a second feature pitch P2. In some embodiments, the second feature pitch P2 is between 90 and 250 microns.

FIG. 3 is a schematic illustration of the power and data signals that may be included in plug 212 comprising conductive vias 220 encapsulated in a dielectric material 208, in accordance with some embodiments. The power and data signals may be associated with two 128 MB DDR memory chips. Advantageously, the diameter of the power signals is configurable to handle various high current densities. Another advantage is that some of the conductive vias shield the pair of conductive vias carrying data signals. While the conductive vias used as shields are shown as being of the same size as the conductive vias 220a, 220b carrying data signals, this is not essential. In various embodiments, the shield conductive vias may have larger of smaller dimensions than the data signal conductive vias 220a, 220b.

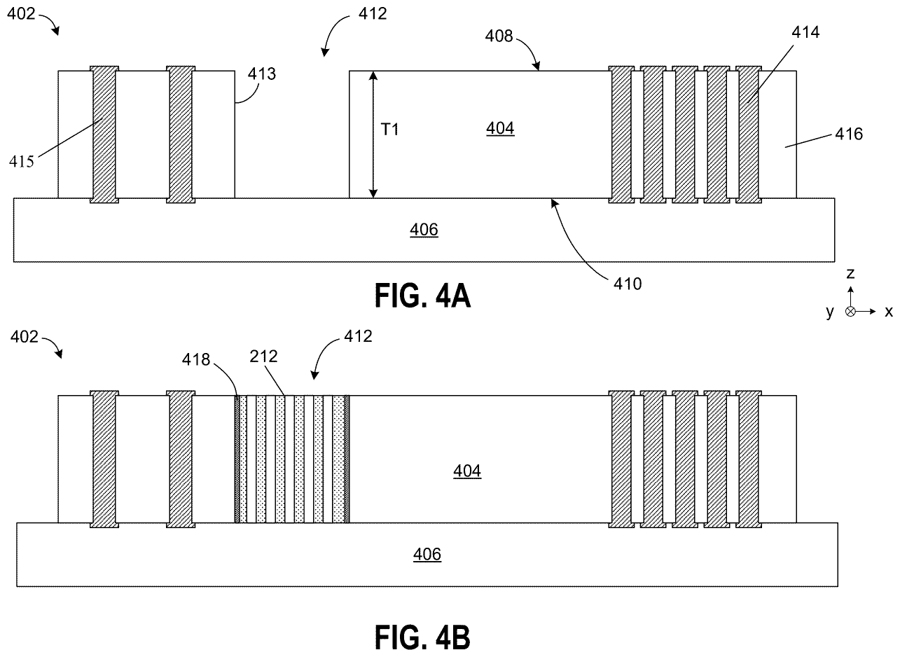

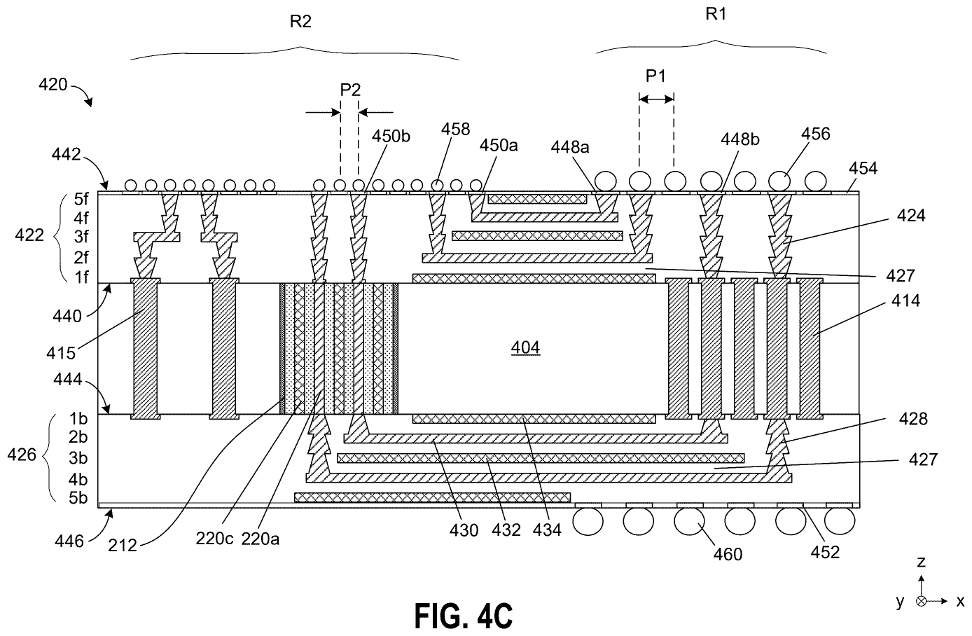

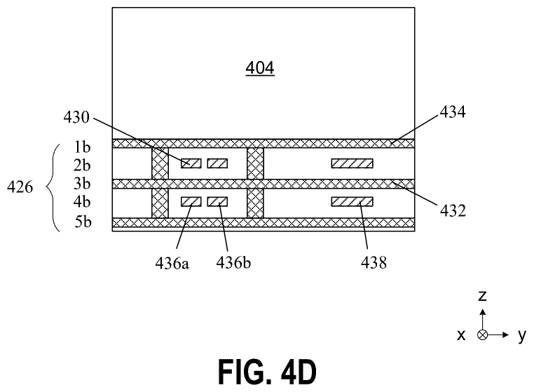

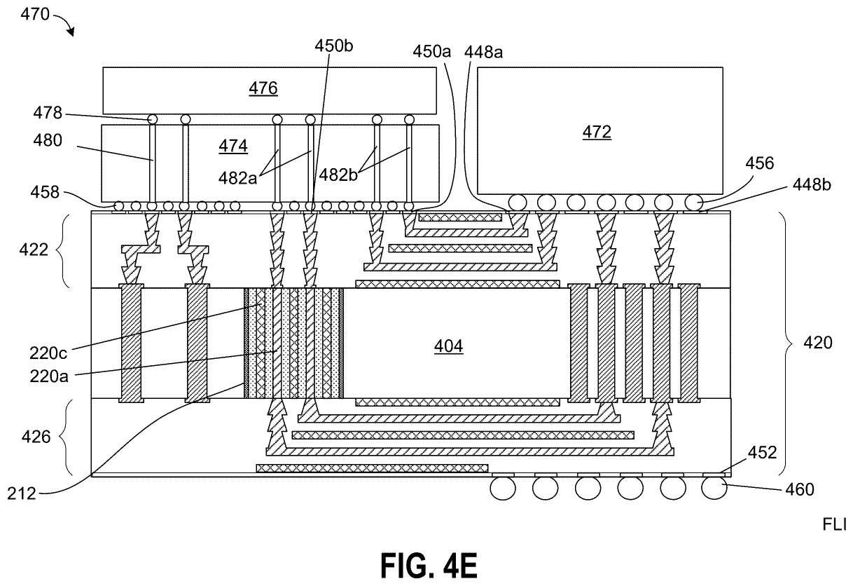

Returning to FIG. 1, methods 101 continue at block 140 with the receipt of a core with at least one through hole and a plurality of through-core vias (TCVs). FIG. 4A is a cross-sectional view of the core 404 after at least one through hole and a plurality of TCVs have been formed in the core, in accordance with some embodiments. The example in FIG. 4A illustrates a second workpiece 402 comprising a substrate core 404 and a carrier 406. The substrate core 404 comprises a first surface 408 and a second surface 410 opposite the first surface. First surface 408 may be referred to as a “front” surface and second surface 410 may be referred to as a “backside” surface. Core 404 may be any preform comprising any material with mechanical rigidity and/or stiffness sufficient to serve as a platform for building up layers of package metallization on front surface 408 and backside surface 410. In embodiments, core 404 comprises a substrate material 416 that may be an organic material that may be reinforced with fibers (e.g., glass fibers or the like).

Substrate core 404 has a thickness T1 that may vary with implementation. In some embodiments, thickness T1 is between 150 μm to 750 μm or greater. The substrate core (or core) 404 includes a plurality of through-substrate vias (TSVs) 414, 415 and a through hole 412. The conductive vias 414, 415 extend from backside surface 410 through IC die substrate material 416 to front surface 408. Build-up layers over the front and backside surfaces are described below. TSVs 414, 415 couple metallization in the build-up layers over the front surface with the build-up layers over the backside surface. TSVs 414, 415 may have any architecture and generally include a metallization, such as, but not limited to, Cu. Because the core 404 comprises an organic material and a laser tool may have limitations, it may not possible or economically feasible to form TSVs 414, 415 with a feature pitch smaller than 150 microns or a diameter smaller than 120 microns. In some examples, TSVs 414, 415 may have a feature pitch in a range of 230 to 250 microns, or a diameter in a range of 180 to 300 microns. Through hole 412 extends from backside surface 410 through substrate material 416 to front surface 408, and includes sidewalls 413. Through hole 412 may be formed using a mechanical tool, such as a drill, a laser, or any other technique known to be suitable for forming holes in organic materials, with or without fillers.

Returning to FIG. 1, methods 101 continue at block 150 where one of the plugs 212 is placed in the through hole 412. FIG. 4B is a cross-sectional view of the core 404 after a plug 212 has been placed in the through hole 412, in accordance with some embodiments. To secure the plug in the through hole, an epoxy material 418, e.g., a bond film, may be provided between sidewalls 213 of plug 212 and sidewalls 413 of through hole 412. Epoxy material 418 may be a non-conductive adhesive. Epoxy material 418 may be polymer matrix that binds the sidewalls together. Plug 212 may be placed in the through hole 412 using in suitable method, e.g., with a pick and place tool.

Returning to FIG. 1, methods 101 continue at block 160 where the carrier is removed and routing structures are formed over surfaces of the core to complete a package substrate. FIG. 4C is a cross-sectional view of a completed package substrate 420, in accordance with some embodiments. Package substrate 420 includes a first routing structure comprising first build-up layers 422 over front surface 408 and a second routing structure comprising second build-up layers 426 over backside surface 410.

In various embodiments, a total of five package layers are required in each of the first and second routing structures. This includes two layers for signals and three layers for ground (Vss). In embodiments, package substrate 420 comprises ten layers (e.g., a 4-2-4 design). A 4-2-4 design is necessary to provide a ground plane above and below each of the signal traces. It is generally a requirement to have the same number of build-up layers over both surfaces. Since the front side of the package substrate includes five routing layers, the backside of the package substrate will also require a set of five routing layers.

The first build-up layers 422 comprise front-side line metallization levels 1f, 2f, 3f, 4f, and 5f, and via metallization 424 between the line metallization levels. The second build-up layers 426 comprise backside line metallization levels 1b, 2b, 3b, 4b, and 5b, and via metallization 428 between the line metallization levels.

In the example illustrated, front-side line metallization levels 2f and 4f are used for signals, and front-side line metallization levels 1f, 3f, and 5f are used for ground (Vss). For clarity, data metallization features and ground metallization features are illustrated with different line patterns. Similarly, backside line metallization levels 2b and 4b are used for signals, and backside line metallization levels 1b, 3b, and 5b are used for ground (Vss). Thus, each metallization level used for signals is vertically between two metallization levels used for ground (Vss). The metallization used for ground (Vss) serve to shield metallization used for signals. For example, the lateral (x-direction) extent of metallization feature 430 in level 2b is shielded by ground metallization feature 432 in level 3b and ground metallization feature 434 in level 1b. Ground metallization features, e.g., features 432, 434, may be coupled to a ground reference Vss of package substrate 420.

FIG. 4D is a cross-sectional view of the second build-up layers 426 of package substrate 420, in accordance with some embodiments. As illustrated in FIG. 4D, each metallization level used for signals is vertically between two metallization levels used for ground (Vss). Metallization levels used for signals may include pairs of conductive traces 436a, 436b used for data signals, e.g., a differential pair of signals, or single conductive traces 438 used for power. The dimensions of conductive traces used for data signals and power may be any suitable dimensions, and are not required to be the same. In an example, the power traces are wider than the data signal traces. Metallization levels used for reference or ground (Vss) may be planes, e.g., ground planes, although this is not essential.

Any number of TCVs 414, 415 may pass through core 404, electrically coupling one or more front-side line metallization levels 1f-5f with one or more backside line metallization levels 1b-5b. Metallization features within package substrate 420 may have been formed with an additive or semi-additive process, for example. In some embodiments, metallization features within package substrate 420 comprise one or more layers of predominantly copper. However, other conductive materials are also possible. The build-up may be performed concurrently on both surfaces of the core 404, or sequentially on the front and back surfaces.

Metallization features in the first and second build-up layers 422, 426 are embedded within one or more layers of package substrate insulator 427. In embodiments, package substrate insulator 427 comprises an organic dielectric material (e.g., comprising a polymer). Package substrate insulator 427 may comprise an epoxy resin, phenolic-glass, or a resinous film such as the GX-series films commercially available from Ajinomoto Fine-Techno Co., Inc.). Exemplary epoxy resins include an acrylate of novolac such as epoxy phenol novolacs (EPN), or epoxy cresol novolacs (ECN). In some specific examples, package substrate insulator 427 is a bisphenol-A epoxy resin, for example including epichlorohydrin. In other examples, package substrate insulator 427 includes bisphenol-F epoxy resin (with epichlorohydrin). In other examples, package substrate insulator 427 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package substrate insulator 427 includes glycidylamine epoxy resin, such as triglycidyl-p-aminophenol (functionality 3) and N,N,N′,N′-tetraglycidyl-bis-(4-aminophenyl)-methane (functionality 4).

The first build-up layers 422 comprise a surface 440 that is proximate to or in contact with the front surface 408 of core 404 and a second surface 442 opposite surface 440. The first build-up layers 422 of the first routing structure include first contacts 448 and second contacts 450 at surface 442. The first contacts 448 are located in a first region R1 on surface 442. The second contacts 450 are located in a second region R2 on surface 442 and may be smaller than first contacts 448. Metallization features used for signals in the first routing structure couple first ones of the first contacts, e.g., contact 448a, with first ones of the second contacts, e.g., contact 450a.

Metallization features used for signals in the second routing structure couple second ones of the first contacts, e.g., contact 448b, with second ones of the second contacts, e.g., contact 450b. As illustrated in FIG. 4C, via metallization 424 couples second ones of the first contacts, e.g., contact 448b, with TCVs 414. Via metallization 428 and line metallization in build-up layers 426 couple TCVs 414 with conductive vias 220 in plug 212. Via metallization 424 also couples second ones of the second contacts, e.g., contact 450b, with conductive vias 220.

In some examples, the first contacts 448 have a feature pitch P1 that is between 300 and 500 microns. In some examples, the second contacts 450 have a feature pitch P2 that is between 110 and 150 microns. In embodiments, a feature pitch P1 of the first contacts 448 is greater than a feature pitch P2 of the second contacts 450.

The second build-up layers 426 comprise a surface 444 that is proximate to or in contact with the backside surface 410 of core 404 and a second surface 446 opposite surface 444. The second build-up layers 426 of the second routing structure include third contacts 452 at surface 446. In the example illustrated contacts 448, 450, and 452 (or pads) are surrounded by a solder resist 454.

In embodiments, interconnects may be formed on surface 442 in preparation for attaching IC dies to package substrate 420. For examples, solder features 456 may be formed on contacts 448, and solder features 458 may be formed on contacts 450. In embodiments, first level interconnects (FLI) may be formed on surface 446 in preparation for packaging or assembly. For examples, solder features 460 may be formed on contacts 452.

Returning to FIG. 1, methods 101 continue at block 170 where IC devices are attached to a routing structure of the package substrate. FIG. 4E is a cross-sectional view of a multi-chip device structure 470 comprising package substrate 420 with a core 404 comprising a conductive vias 220 embedded in a plug 212 in the core after IC devices have been attached to a first routing structure comprising first build-up layers 422, in accordance with some embodiments.

In the example illustrated in FIG. 4E, a first IC device 472 is attached to package substrate 420 with solder features 456, a base IC device 474 is attached to package substrate 420 with solder features 458, and a second IC device 476 is attached to the second IC device 474 with solder features 478.

The example multi-chip device structure 470 includes two 128 MB DDR memory chips. In the example, first IC device 472 is or includes memory, e.g., two 128 MB DDR memory chips. The base IC device 474 may be a passive component. The second IC device 476 may be stacked on second IC device 474. The second IC device 476 may be an active component comprising circuitry for performing any desired function, e.g., the second IC device 476 may be processor or include other types of logic.

The base IC device 474 can include conductive vias 480 and 482 to provide electrical continuity between the contacts 450 interconnect of package substrate 420 and second IC device 476. The conductive vias 480 may couple power signals between contacts 452 of package substrate 420 and second IC device 476. The conductive vias 482 may couple data signals between first IC device 472 and second IC device 476. For example, conductive vias 482a may carry a backside channel of DDR memory signals and conductive vias 482b may carry a front side channel of DDR memory signals. In some examples, the base IC device 474 may be an active component that includes active devices, e.g., transistors (not shown).

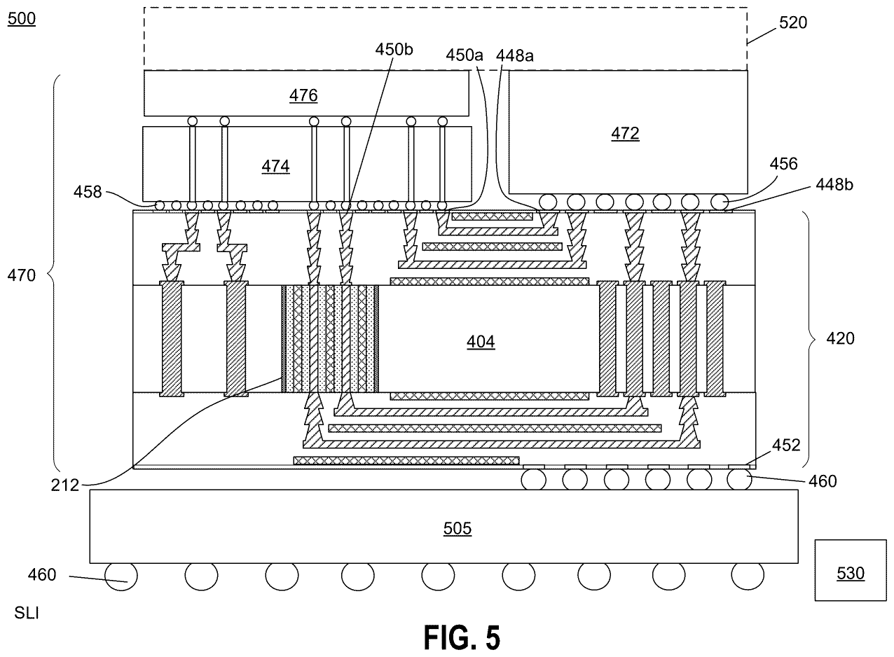

Returning to FIG. 1, methods 101 end at block 180 end with the completion of the multi-chip device package structures. FIG. 5 is a cross-sectional view of a system 500 including multi-chip device structure 470 attached to a host component 505 by reflowing FLI interconnects 460, in accordance with some embodiments. In exemplary embodiments, FLI interconnects 460 are solder (e.g., SAC) microbumps although other interconnect features are also possible. In some embodiments, host component 505 is predominantly silicon. Host component 505 may also comprise one or more alternative materials known to be suitable as interposers or package substrates (e.g., an epoxy preform, cored or coreless laminate board, etc.). Host component 505 may include one or more metallized redistribution levels (not depicted) embedded within a dielectric material. Host component 505 may also include one or more IC die embedded therein.

As illustrated in dashed line, one or more heat spreaders and/or heat sinks 520 may be further coupled to multi-chip device structure 470, which may be advantageous, for example, where IC dies 472, 476 comprise one or more CPU cores or other circuitry of similar power density. Host component 505, may, for example, may be coupled with a primary power supply 530. The power supply 530 be external to or integrated within host component 505. The power supply 530 serves to receive a mains electrical input and output one or more system power supply rails based on the mains input. In some embodiments, the package substrate ground Vss planes are coupled a ground reference of the power supply output.

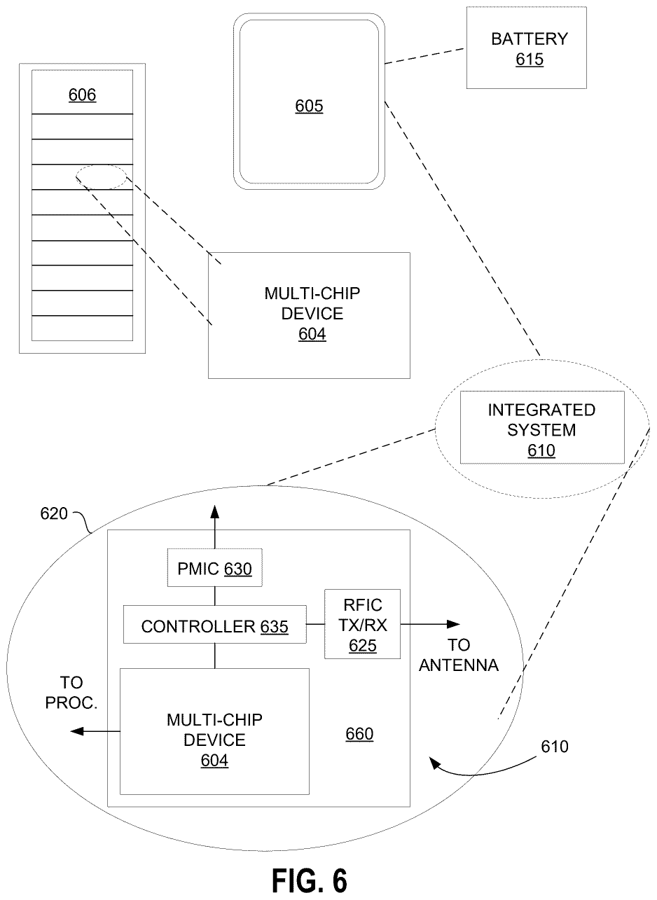

FIG. 6 illustrates a mobile computing platform and a data server machine employing a multi-chip device structure 604 comprising package substrate with a core comprising a conductive vias embedded in a plug comprising a dielectric material and IC devices attached to the package substrate, for example as described elsewhere herein. Server machine 606 may be any commercial server, for example including any number of high-performance computing platforms disposed within a rack and networked together for electronic data processing, which in the exemplary embodiment includes multi-chip device structure 604, for example as described elsewhere herein. The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), a chip-level or package-level integrated system 610, and a battery 615.

Whether disposed within the integrated system 610 illustrated in the expanded view 620, or as a stand-alone package within the server machine 606, the integrated system or server machine includes multi-chip device structure 604, for example as described elsewhere herein. Multi-chip device structure 604 may be further coupled to a host substrate 660, along with, one or more of a power management integrated circuit (PMIC) 630, RF (wireless) integrated circuit (RFIC) 625 including a wideband RF (wireless) transmitter and/or receiver (TX/RX) (e.g., including a digital baseband and an analog front-end module further comprises a power amplifier on a transmit path and a low noise amplifier on a receive path), and a controller 635. PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

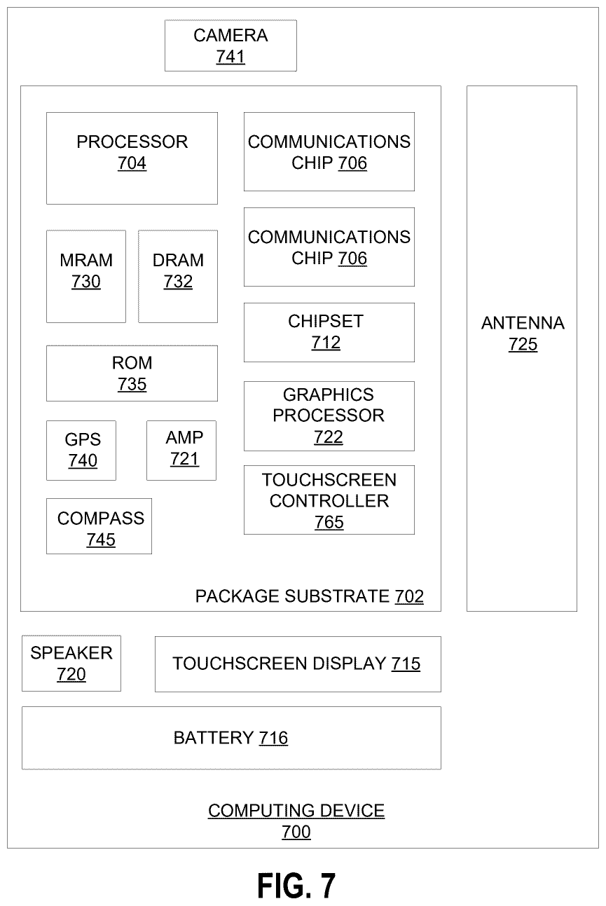

FIG. 7 is a functional block diagram of an electronic computing device 700, in accordance with some embodiments. The computing device 700 may include any of the devices or structures discussed elsewhere herein, e.g., a multi-chip device structure comprising a package substrate with a core comprising a conductive vias embedded in a plug comprising a dielectric material and IC devices attached to the package substrate. Device 700 further includes a package substrate 702 hosting a number of components, such as, but not limited to, a processor 704 (e.g., an applications processor). Processor 704 may be physically and/or electrically coupled to package substrate 702. In some examples, processor 704 is within system 500, for example, as described elsewhere herein. Processor 704 may be implemented with circuitry in either or both of a host IC chip and a chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to the package substrate 702. In further implementations, communication chips 706 may be part of processor 704. Depending on its applications, computing device 700 may include other components that may or may not be physically and electrically coupled to package substrate 702. These other components include, but are not limited to, volatile memory (e.g., DRAM 732), non-volatile memory (e.g., ROM 735), flash memory (e.g., NAND or NOR), magnetic memory (MRAM 730), a graphics processor 722, a digital signal processor, a crypto processor, a chipset 712, an antenna 725, touchscreen display 715, touchscreen controller 765, battery 716, audio codec, video codec, power amplifier 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth), or the like. In some exemplary embodiments, one or more of the functional blocks noted above are within multi-chip device structure 470, described elsewhere herein. For example, processor 704 may be implemented within circuitry in an IC die attached to a package substrate with a core comprising a conductive vias embedded in a plug comprising a dielectric material, described elsewhere herein. In addition, an electronic memory (e.g., MRAM 730 or DRAM 732) may be implemented with circuitry in an IC die attached to a package substrate with a core comprising a conductive vias embedded in a plug comprising a dielectric material, described elsewhere herein.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 706 may implement any of a number of wireless standards or protocols. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus, comprising: a package substrate comprising a core comprising a first surface, a second surface opposite the first surface, a plurality of first conductive vias, and a through hole; a plug in the through hole, the plug comprising a dielectric material and a plurality of second conductive vias extending through the dielectric material; a first routing structure over the first surface, the first routing structure comprising first and second contacts at a third surface of the first routing structure away from the first surface, wherein a pitch of the first contacts is greater than a pitch of the second contacts, and the first routing structure couples first ones of the first contacts with first ones of the second contacts; and a second routing structure over the second surface, the second routing structure coupling the first conductive vias with the second conductive vias, and coupling second ones of the first contacts with second ones of the second contacts.

Example 2: The apparatus of claim 1, wherein the pitch of the first contacts is greater than 300 microns and the pitch of the second contacts is less than 150 microns.

Example 3: The apparatus of example 1 or example 2, wherein a diameter of the first conductive vias is greater than a diameter of the second conductive vias.

Example 4: The apparatus of any of examples 1 through 3, wherein a diameter of the first conductive vias is greater than 175 microns and a diameter of the second conductive vias is less than 90 microns.

Example 5: The apparatus of any of examples 1 through 4, further comprising an epoxy between a sidewall of the through hole and a sidewall of the plug.

Example 6: The apparatus of any of examples 1 through 5, wherein the core comprises an organic dielectric material of different composition than the dielectric material of the plug.

Example 7: The apparatus of any of examples 1 through 6, further comprising: a first integrated circuit (IC) device comprising third contacts coupled with the first contacts; and a second IC device comprising fourth contacts coupled with the second contacts.

Example 8: The apparatus of example 7, further comprising a third IC device coupled with the second IC device, wherein the second IC device is a passive device and the first IC device comprises memory circuitry.

Example 9: The apparatus of any of examples 1 through 7, wherein the first routing structure comprises: a first layer over the first surface, the first layer comprising a first ground metallization feature; a second layer over the first layer, the second layer comprising a first conductive feature; a third layer over the second layer, the third layer comprising a second ground metallization feature; a fourth layer over the third layer, the fourth layer comprising a second conductive feature; and a fifth layer over the fourth layer, the fifth layer comprising a third ground metallization feature.

Example 10: The apparatus of example 9, wherein the second routing structure comprises: a sixth layer over the second surface, the sixth layer comprising a fourth ground metallization feature; a seventh layer over the sixth layer, the seventh layer comprising a third conductive feature; an eighth layer over the seventh layer, the eighth layer comprising a fifth ground metallization feature; a ninth layer over the eighth layer, the ninth layer comprising a fourth conductive feature; and a tenth layer over the ninth layer, the tenth layer comprising a sixth ground metallization feature.

Example 11: The apparatus of any of examples 1 through 7, or example 9, wherein the first contacts are in a first region on the third surface and the second contacts are in a second region on the third surface.

Example 12: The apparatus of any of examples 1 through 7, or examples 9 or 10, wherein a diameter of the first conductive vias is greater than a diameter of the second conductive vias.

Example 13: The apparatus of any of examples 1 through 7, or examples 9 through 11, wherein the apparatus is included in a system comprising: a first integrated circuit (IC) device comprising third contacts coupled with the first contacts; a second IC device comprising fourth contacts coupled with the second contacts; a host component coupled to the second routing structure by a plurality of solder features; and a power supply coupled to the first and second IC devices through the package substrate.

Example 14: An apparatus, comprising: a package substrate comprising a core between a front-side routing structure and a backside routing structure, wherein the core comprises a plurality of first conductive vias, and a through hole, and the front-side routing structure comprising first and second contacts at a surface of the package substrate; a first IC device comprising a memory coupled with the first contacts; a second IC die coupled with the second contacts; wherein a front-side routing structure comprises a front-side memory signal channel coupling the first and second IC devices, and coupling first ones of the first contacts with first ones of the second contacts; wherein the backside routing structure comprises a backside memory signal channel coupling the first and second IC devices; and a plug in the through hole comprising a dielectric material and a plurality of second conductive vias extending through the dielectric material, wherein the first and second conductive vias couple the backside memory signal channel with second ones of the first contacts and couple the backside memory signal channel with second ones of the second contacts.

Example 15: The apparatus of example 14, wherein first ones of the plurality of second conductive vias comprise a first diameter, second ones of the second vias comprise a second diameter, and the second diameter is larger than the first diameter.

Example 16: The apparatus of example 14 or example 15, wherein a diameter of the first conductive vias is greater than a diameter of the first ones of the second conductive vias.

Example 17: The apparatus of example 15, further comprising: a first integrated circuit (IC) device comprising third contacts coupled with the first contacts; a second IC device comprising fourth contacts coupled with the second contacts; and a power supply coupled with the package substrate, wherein the second ones of the second vias are to conduct a power signal generated by the power supply.

Example 18: A method comprising: forming a plurality of first conductive vias and a through hole in a core; applying a mold material over a plurality of conductive columns attached to a carrier to form a mold plug comprising a plurality of second conductive vias; planarizing the mold plug, removing the mold plug from the carrier, and placing the mold plug in the through hole; and providing a bond film between a sidewall of the mold plug and a sidewall of the through hole.

Example 19: The method of example 18, further comprising forming a first routing structure over a first surface of the core and forming a second routing structure over a second surface opposite the first surface, the forming the second routing structure comprising: forming a first layer over the second surface, the first layer comprising a first ground metallization feature; forming a second layer over the first layer, the second layer comprising a first conductive feature coupled with a first one of the first conductive vias and a first one of the second conductive vias; forming a third layer over the second layer, the third layer comprising a second ground metallization feature; forming a fourth layer over the third layer, the fourth layer comprising a second conductive feature coupled with a second one of the first conductive vias and a second one of the second conductive vias; and forming a fifth layer over the fourth layer, the fifth layer comprising a third ground metallization feature.

Example 20: The method of example 18, further comprising: attaching a first integrated circuit (IC) device to first contacts on a surface of the first routing structure; and attaching a second IC device to second contacts on the surface of the first routing structure.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a package substrate comprising a core comprising a first surface, a second surface opposite the first surface, a plurality of first conductive vias, and a through hole;
a plug in the through hole, the plug comprising a dielectric material and a plurality of second conductive vias extending through the dielectric material;
a first routing structure over the first surface, the first routing structure comprising first and second contacts at a third surface of the first routing structure away from the first surface, wherein a pitch of the first contacts is greater than a pitch of the second contacts, and the first routing structure couples first ones of the first contacts with first ones of the second contacts; and
a second routing structure over the second surface, the second routing structure coupling the first conductive vias with the second conductive vias, and coupling second ones of the first contacts with second ones of the second contacts.

2. The apparatus of claim 1, wherein the pitch of the first contacts is greater than 300 microns and the pitch of the second contacts is less than 150 microns.

3. The apparatus of claim 1, wherein a diameter of the first conductive vias is greater than a diameter of the second conductive vias.

4. The apparatus of claim 1, wherein a diameter of the first conductive vias is greater than 175 microns and a diameter of the second conductive vias is less than 90 microns.

5. The apparatus of claim 1, further comprising an epoxy between a sidewall of the through hole and a sidewall of the plug.

6. The apparatus of claim 1, wherein the core comprises an organic dielectric material of different composition than the dielectric material of the plug.

7. The apparatus of claim 1, further comprising:
a first integrated circuit (IC) device comprising third contacts coupled with the first contacts; and
a second IC device comprising fourth contacts coupled with the second contacts.

8. The apparatus of claim 7, further comprising a third IC device coupled with the second IC device, wherein the second IC device is a passive device and the first IC device comprises memory circuitry.

9. The apparatus of claim 1, wherein the first routing structure comprises:
a first layer over the first surface, the first layer comprising a first ground metallization feature;
a second layer over the first layer, the second layer comprising a first conductive feature;
a third layer over the second layer, the third layer comprising a second ground metallization feature;
a fourth layer over the third layer, the fourth layer comprising a second conductive feature; and
a fifth layer over the fourth layer, the fifth layer comprising a third ground metallization feature.

10. The apparatus of claim 9, wherein the second routing structure comprises:
a sixth layer over the second surface, the sixth layer comprising a fourth ground metallization feature;
a seventh layer over the sixth layer, the seventh layer comprising a third conductive feature;
an eighth layer over the seventh layer, the eighth layer comprising a fifth ground metallization feature;
a ninth layer over the eighth layer, the ninth layer comprising a fourth conductive feature; and
a tenth layer over the fourth layer, the ninth layer comprising a sixth ground metallization feature.

11. The apparatus of claim 1, wherein the first contacts are in a first region on the third surface and the second contacts are in a second region on the third surface.

12. The apparatus of claim 1, wherein a diameter of the first conductive vias is greater than a diameter of the second conductive vias.

13. The apparatus of claim 1, wherein the apparatus is included in a system comprising:
a first integrated circuit (IC) device comprising third contacts coupled with the first contacts;
a second IC device comprising fourth contacts coupled with the second contacts;
a host component coupled to the second routing structure by a plurality of solder features; and
a power supply coupled to the first and second IC devices through the package substrate.

14. An apparatus, comprising:
a package substrate comprising a core between a front-side routing structure and a backside routing structure, wherein the core comprises a plurality of first conductive vias, and a through hole, and the front-side routing structure comprising first and second contacts at a surface of the package substrate;
a first IC device comprising a memory coupled with the first contacts;
a second IC die coupled with the second contacts;
wherein a front-side routing structure comprises a front-side memory signal channel coupling the first and second IC devices, and coupling first ones of the first contacts with first ones of the second contacts;
wherein the backside routing structure comprises a backside memory signal channel coupling the first and second IC devices; and
a plug in the through hole comprising a dielectric material and a plurality of second conductive vias extending through the dielectric material, wherein the first and second conductive vias couple the backside memory signal channel with second ones of the first contacts and couple the backside memory signal channel with second ones of the second contacts.

15. The apparatus of claim 14, wherein first ones of the plurality of second conductive vias comprise a first diameter, second ones of the second vias comprise a second diameter, and the second diameter is larger than the first diameter.

16. The apparatus of claim 15, wherein a diameter of the first conductive vias is greater than a diameter of the first ones of the second conductive vias.

17. The apparatus of claim 15, further comprising:
a first integrated circuit (IC) device comprising third contacts coupled with the first contacts;
a second IC device comprising fourth contacts coupled with the second contacts; and
a power supply coupled with the package substrate, wherein the second ones of the second vias are to conduct a power signal generated by the power supply.

18. A method comprising:
forming a plurality of first conductive vias and a through hole in a core;
applying a mold material over a plurality of conductive columns attached to a carrier to form a mold plug comprising a plurality of second conductive vias;
planarizing the mold plug, removing the mold plug from the carrier, and placing the mold plug in the through hole; and
providing a bond film between a sidewall of the mold plug and a sidewall of the through hole.

19. The method of claim 18, further comprising forming a first routing structure over a first surface of the core and forming a second routing structure over a second surface opposite the first surface, the forming the second routing structure comprising:
forming a first layer over the second surface, the first layer comprising a first ground metallization feature;
forming a second layer over the first layer, the second layer comprising a first conductive feature coupled with a first one of the first conductive vias and a first one of the second conductive vias;
forming a third layer over the second layer, the third layer comprising a second ground metallization feature;
forming a fourth layer over the third layer, the fourth layer comprising a second conductive feature coupled with a second one of the first conductive vias and a second one of the second conductive vias; and
forming a fifth layer over the fourth layer, the fifth layer comprising a third ground metallization feature.

20. The method of claim 19, further comprising:
attaching a first integrated circuit (IC) device to first contacts on a surface of the first routing structure; and
attaching a second IC device to second contacts on the surface of the first routing structure.
